(19) United States
(12) Patent Application Publication
(10) Pub. No.: US 2024/0334600 A1
(43) Pub. Date: Oct. 3, 2024

(54) PRINTED CIRCUIT BOARDS INCLUDING DIRECT ROUTING FROM INTEGRATED CIRCUIT PACKAGES

(71) Applicant: Intel Corporation, Santa Clara, CA (US)

(72) Inventors: Min Suet Lim, Gelugor (MY); Rijo Kizhakkedathu Avarachan, Bayan Lepas (MY); Eng Huat Goh, Ayer Itam (MY)

(21) Appl. No.: 18/739,944

(22) Filed: Jun. 11, 2024

(51) Int. Cl. H05K 1/11; H01L 23/00; H05K 1/18; H10B 80/00

(52) U.S. Cl. CPC H05K 1/111; H05K 1/181; H01L 24/16; H01L 2224/16227; H05K 2201/10159; H10B 80/00

(57) ABSTRACT

Printed circuit boards including direct routing from integrated circuit packages are disclosed. An example substrate disclosed herein including a first contact pad array to receive an integrated circuit package, a second contact pad array to receive a memory die, the first contact pad array having a matching arrangement as the second contact pad array, and a layer including a plurality of interconnections extending between the first contact pad array and the second contact pad array.

### BACKGROUND

In many electronic devices, integrated circuit (IC) packages and/or semiconductor dies are connected to larger circuit boards such as motherboards and/or other types of printed circuit boards (PCBs). Memory, input/output devices, and integrated circuit package can be coupled to printed circuit boards via a variety of connections, such as ball grid arrays (BGAs) or land grid arrays (LGAs). These printed circuit boards include substrates that include traces, which electrically couple the components mounted on the printed circuit boards.

### BRIEF DESCRIPTION OF THE DRAWINGS

FIG. 1 is a perspective view of an example printed circuit board assembly including an example integrated circuit package and an example printed circuit board implemented in accordance with teachings of this disclosure.

FIG. 2 is a schematic diagram of a prior substrate including a prior trace configuration.

FIG. 3 is a schematic diagram of the example printed circuit board of FIG. 1 including an example trace configuration constructed in accordance with teachings of this disclosure.

FIG. 4 is a schematic diagram of the prior printed circuit board assembly of FIG. 2.

FIG. 5 is a schematic diagram of the example printed circuit board assembly of FIG. 3.

FIG. 6 is a schematic diagram of another example printed circuit board assembly including another example trace configuration implemented in accordance with teachings of this disclosure.

FIG. 7A is a schematic side-view diagram of the prior printed circuit board assembly of FIG. 4.

FIG. 7B is a schematic side-view diagram of the example printed circuit board assembly of FIG. 5.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Many electronic devices, such as mobile electronic devices, have confined packaging spaces for electronic components. Some such electronic devices include system-on-chip (SOC) packages. System-on-chips are integrated circuit packages that include some or all of the electronic components of a compute system incorporated into a single integrated circuit package. For example, system-on-chip packages can include central processing units, graphic processing units, memory interfaces, input/output interfaces, etc. Integrated circuit packages, such as SOC packages, can be mounted on a printed circuit board (PCB) via a ball grid array (BGA) and/or another surface mount system. PCBs include a plurality of traces, which extend between the contact pads of the BGA mounting the integrated circuitry package and the contact pads of the BGAs mounting other components on the PCB, such as input/output devices and memory units.

Some prior printed circuit board assemblies include BGA contact pads with different arrangements to accommodate the configuration of the mounted devices. For instance, prior PCBs can include BGA contact pads that receive the integrated circuit package with a configuration that is different than the arrangement of the BGA contact pads that receive the memory unit mounted to the printed circuit board. In some such instances, the different arrangements of the contact pads of the BGAs cause the traces between the BGAs to fanout and/or swizzle, which increases the physical area occupied by the traces and the overall size of the printed circuit board. The size of the printed circuit board can constrain the design of electronic devices including such printed circuit boards.

Examples disclosed herein overcome some or all of the above-noted deficiencies and include printed circuit boards with substrates with ball grid array (BGA) contact pads having a same arrangement for different components (e.g., an IC package and a memory unit) to be electrically coupled through the printed circuit boards. The example substrates described herein include trace configurations that reduce (e.g., prevent, etc.) the swizzling and un-swizzling of the traces extending between the contact pads associated with the integrated circuit package and the contact pads associated with the memory unit. Examples disclosed herein include trace configurations with traces that are parallel in the portion of the PCB between the portions of the PCB containing the contact pads for the different components to be electrically coupled. Some examples disclosed herein include sets of ball grid array contact pads that included longitudinally aligned data bit pads and longitudinally aligned address/command bit pads. Some examples disclosed herein reduce the longitudinal distance between ball grid array contact pads by 200% relative to known known PCB configurations.

As used herein, the orientation of features is described with reference to a lateral axis, a vertical axis, and a longitudinal axis of a printed circuit board assembly. As used herein, the vertical axis is perpendicular to the plane of the substrate of the printed circuit board. As used herein, the longitudinal axis is perpendicular to the vertical axis and is the major axis that the memory dies and integrated circuit packages are displaced along. That is, a line extending parallel to the longitudinal axis would pass through both the integrated circuit package and the memory unit. As used herein, the lateral axis is perpendicular to the longitudinal axis and the vertical axis. Thus, a line extending parallel to the lateral axis would pass between adjacent edges of the integrated circuit package and the memory unit. In general, the attached figures are annotated with a set of axes including the longitudinal axis X, the lateral axis Y, and the vertical axis Z.

As used herein, a group of contact pads on a printed circuit board or a package substrate that enabling the coupling of a feature (e.g., a semiconductor die) onto the printed circuit board or the package substrate is referred to as a “contact pad array.” As used herein, the “arrangement” of a contact pad array refers to the two-dimensional (2D) distribution, footprint, and functional ordering of the contact pads within a contact pad array. As used herein, the “2D distribution” of a contact pad array refers to the physical spacing and layout of contact pads within a contact pad array (e.g., number, length, and positioning of rows and/or columns of contact pads in the array). As used herein, the “footprint” of the contact pad array refers to the size and shape of the physical area of the associated substrate occupied by the contact pad array. As used herein, the “functional ordering” refers to the mapping of bit/bytes to the contact pads of a contact pad array. The functional ordering of a contact pad array refers to both the overall ordering (e.g., location, placement, etc.) of contact pads that send/receive data bits (referred to herein as “data contact pads”) and address, command, and clock (CAC) bits (referred to herein as “address contact pads”) within a set of contact pads and the specific ordering (e.g., location, placement, etc.) of contact pads within the set of contact pads. The arrangement of contact pad arrays can be based on the specific Joint Electron Device Engineering Council (JEDEC) standard associated with the contact pad array. As used herein, the term “trace configuration” refers to the pattern of traces extending through a printed circuit board and/or an integrated circuit package.

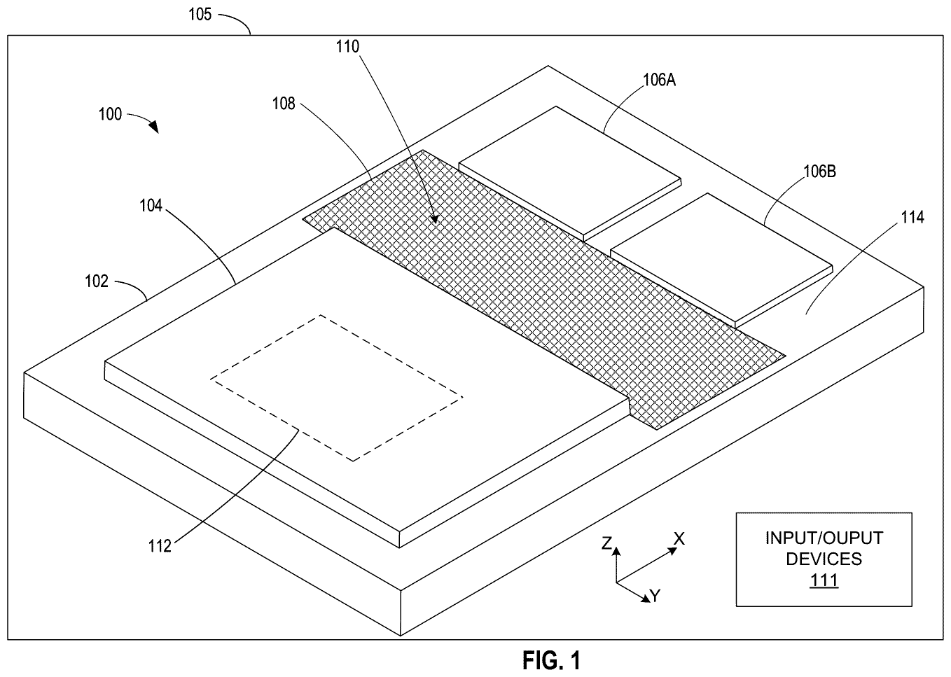

FIG. 1 is a perspective view of an example printed circuit board assembly 100 including an example printed circuit board 102 and an example integrated circuit package 104 implemented in accordance with teachings of this disclosure. In the illustrated example of FIG. 1, the printed circuit board assembly 100 is disposed in an example electronic device 105. In the illustrated example of FIG. 1, the printed circuit board assembly 100 includes an example first memory die 106A and an example second memory die 106B. In the illustrated example of FIG. 1, the printed circuit board 102 includes an example first region 108 that is disposed between the integrated circuit package 104 and memory dies 106A, 106B, which includes example traces 110. Although the first region 108 and the traces 110 are represented on the surface of the printed circuit board 102, the first region 108 includes the entire thickness of the printed circuit board 102 between the integrated circuit package 104 and memory dies 106A, 106B. Further, the traces 110 can be on the surface of the printed circuit board 102 (as shown) or at any vertical position within the thickness of the printed circuit board 102. In the illustrated example of FIG. 1, the traces 110 extend between the integrated circuit package 104 and the memory dies 106A, 106B. In the illustrated example of FIG. 1, the printed circuit board assembly 100 includes example traces 110, which extend between the memory dies 106A, 106B and the integrated circuit package 104.

The electronic device 105 houses and is operated by the printed circuit board assembly 100. In some examples, the electronic device 105 can be implemented by a mobile device, such as a cell phone, a smart phone, a laptop, a tablet, a smartwatch, etc. In some such examples, the packaging space of the electronic device 105 is limited by the mobile functionality of the electronic device 105. Accordingly, the form factor and size of the printed circuit board assembly 100 is limited by the size of the electronic device 105. In other examples, the electronic device 105 can be implemented by another type of electronic device including a server, a personal computer, a workstation, a self-learning machine (e.g., a neural network), a personal digital assistant (PDA), an Internet appliance, a headset (e.g., an augmented reality (AR) headset, a virtual reality (VR) headset, etc.) or other wearable device, or any other type of computing and/or electronic device.

In some examples, the electronic device 105 includes an example plurality of input/output devices 111, which enables information to be sent/received by the printed circuit board assembly 100. For example, the input/output devices 111 can include one or more displays, one or more touch screens, one or more keypads, one or more switches, one or more buttons, one or more speakers, one or more microphones, one or more tactile feedback systems, etc. In some such examples, the input/output devices 111 can be electrically coupled to the integrated circuit package 104 via one or more general-purpose input/output (GPIO) interfaces and/or one or more high-speed input/output (HSIO) interfaces.

The printed circuit board 102 is the platform that mounts and supports the integrated circuit package 104 and the memory dies 106A, 106B. In some examples, the printed circuit board 102 includes multiple trace-including layers separated from one another by layers of dielectric material and interconnected by electrically conductive vias. In some such examples, the printed circuit board 102 includes a plurality of traces that couple the components mounted on the printed circuit board 102 (e.g., the traces 110 that couple the integrated circuit package 104 and the memory dies 106A, 106B, etc.). In some examples, the traces of the printed circuit board 102 are formed in circuit pattern(s) to route electrical signals between the components coupled to the printed circuit board 102.

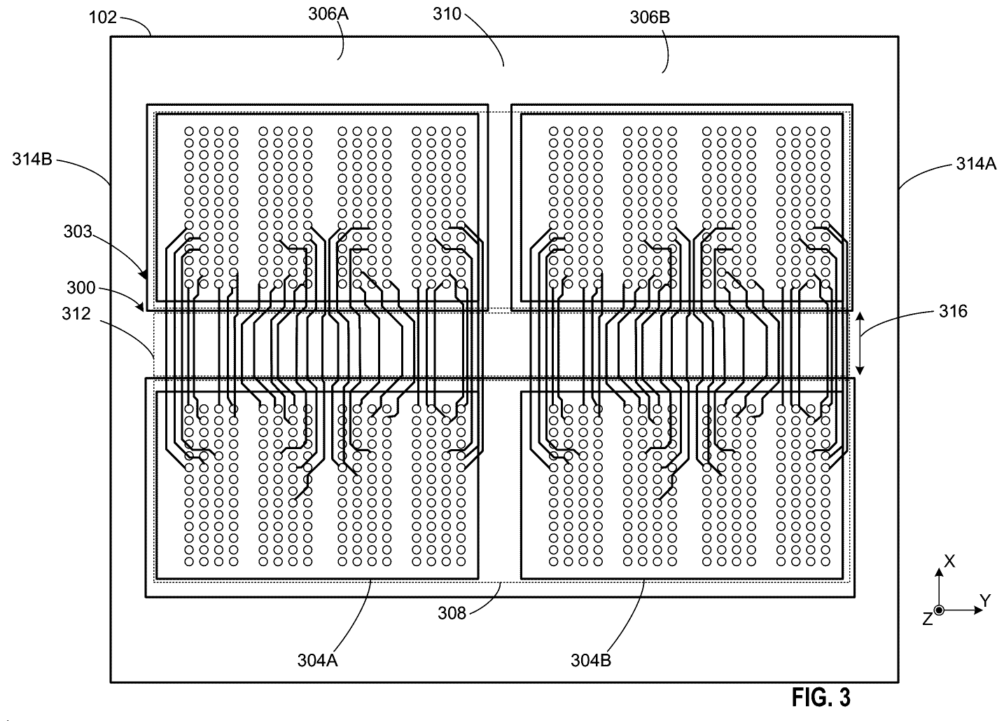

The integrated circuit package 104 includes one or more dies and related electric components coupled to a package substrate. In the illustrated example of FIG. 1, the integrated circuit package 104 includes an example semiconductor die 112. Semiconductor dies, like the semiconductor die 112 and memory dies 106A, 106B, are also referred to herein as “silicon dies,” “chips,” and/or “chiplets.” In some examples, the semiconductor die 112 and/or the other components of the integrated circuit package 104 can be enclosed by a package lid and/or mold (not illustrated), which houses and/or protects the components of the integrated circuit package 104. The integrated circuit package 104 is electrically coupled to an example surface 114 of the printed circuit board 102 via a plurality of contact pads and/or lands. In some examples, the integrated circuit package 104 can include a plurality of balls, pins, and/or pads to facilitate the mounting of the integrated circuit package 104 to the printed circuit board 102. The contact pads of the printed circuit board 102 that receive the integrated circuit package 104 are described below in conjunction with FIG. 3.

In the illustrated example of FIG. 1, the integrated circuit package 104 is a system-on-chip (SOC) package, which includes some or all of the components associated with the printed circuit board assembly 100. For example, the integrated circuit package 104 can include a central processing unit (e.g., a processor die, etc.), a graphical processing unit, memory interfaces, input/output (I/O) interfaces, etc. In other examples, the integrated circuit package 104 can be implemented by another type of integrated circuit package (e.g., a central processing unit, a graphic processing unit, a digital signal processor, an accelerator, etc.).

The memory dies 106A, 106B are memory devices that store digital data associated with the operation of the electronic device 105. For example, the memory dies 106A, 106B can include the digital data associated with the operation of the integrated circuit package 104, the operation of the integrated circuit package 104, and/or other working data used by the semiconductor die 112 during the operation of the electronic device 105. In some examples, the memory dies 106A, 106B are double data rate (DDR) memory units. The memory dies 106A, 106B are electrically coupled to the surface 114 of the printed circuit board 102 via a plurality of contact pads and/or lands. In some examples, the memory dies 106A, 106B can include a plurality of balls, pins, and/or pads to facilitate the coupling of the memory dies 106A, 106B to the printed circuit board 102. The contact pads of the printed circuit board 102 that receive the memory dies 106A, 106B are described below in conjunction with FIG. 3.

In some examples, the memory dies 106A, 106B are dynamic random-access (DRAM) units. Additionally or alternatively, one or both of the memory dies 106A, 106B can be implemented by another type of volatile memory die (e.g., static random-access memory, etc.). Additionally or alternatively, one or both of the memory dies 106A, 106B can be implemented by non-volatile memory dies (e.g., read-only memory dies, a flash memory die, a solid-state storage die, etc.). In some examples, the printed circuit board assembly 100 includes only a single memory die. In other examples, the printed circuit board assembly 100 includes more than two memory dies.

The traces 110 are conductive tracks (e.g., conductive paths, etc.) that transmit electrical signals (e.g., electrically couple, etc.) between locations in the printed circuit board 102. The traces 110 can be surrounded by dielectric material (e.g., non-conductive material, etc.) to mitigate (e.g., reduce, prevent, etc.) crosstalk (e.g., signal leakage, etc.) between traces in the printed circuit board 102. As used herein, the terms “traces” and “interconnects” are used interchangeably to refer to the conductive paths or routing that transmit information within the substrate of the printed circuit board 102 and/or the package substrate of the integrated circuit package 104. In some examples, the traces 110 in the region 108 are disposed in multiple layers of the printed circuit board 102. In some examples, the spacing between the traces 110 is driven by a permitted crosstalk margin (e.g., reducing the spacing between the traces 110 increases signal leakage between adjacent traces, etc.). In some examples, the width of the traces 110 is driven by the impedance of electric signals transmitted through the traces 110 (e.g., thinner traces have greater impedances than wider traces, etc.) and/or the processed used to create the traces 110 during the fabrication of the printed circuit board 102. In some such examples, the density of the traces 110 in the first region 108 is limited by the crosstalk margin and/or thickness of the traces 110.

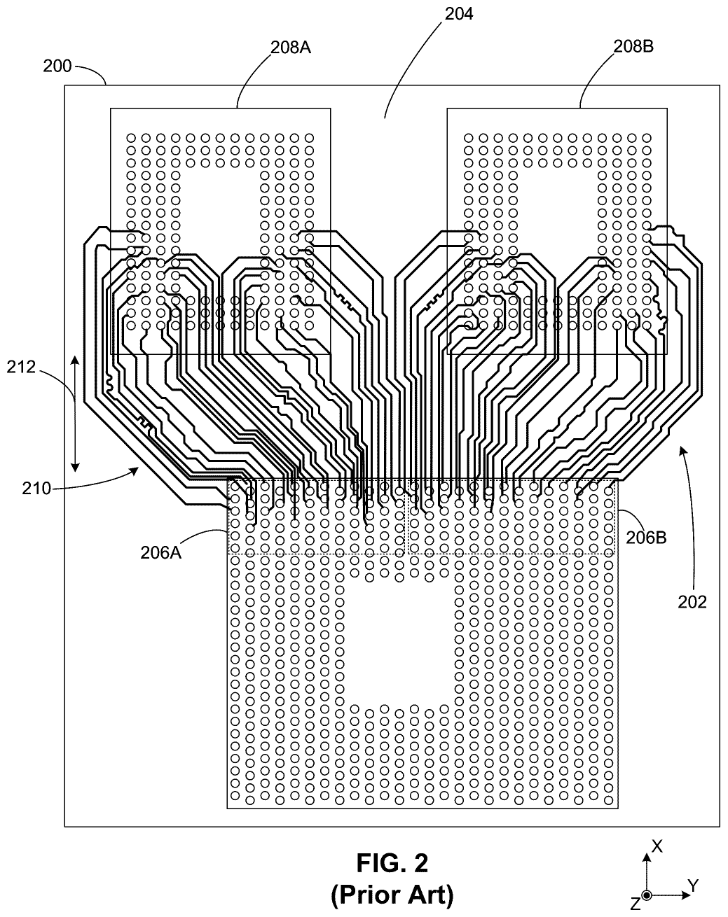

In the illustrated example of FIG. 1, the traces 110 in the region 108 extend between the contact pads of the printed circuit board 102 that receive (e.g., electrically couple with) the integrated circuit package 104 and the contact pads of the printed circuit board 102 that receive (e.g., electrically couple with) the memory dies 106A, 106B. A known trace configuration is described in conjunction with FIG. 2. Example trace configurations implemented in accordance with teachings of this disclosure are described below in conjunction with FIG. 3. While examples described herein are described with references to the connections between the integrated circuit package 104 and the memory dies 106A, 106B, the example trace configurations described herein are not limited to connections between integrated circuit packages 104 and the memory dies 106A, 106B. Rather, examples disclosed herein can be implemented to interconnect any types of semiconductor devices (e.g., chips, dies, etc.)

FIG. 2 is a schematic diagram of a printed circuit board 200 including a known trace configuration 202. In FIG. 2, a mount surface 204 of the printed circuit board 200 includes a first package-side contact pad array 206A, a second package-side contact pad array 206B, a first memory-side contact pad array 208A, and a second memory-side contact pad array 208B. The contact pad arrays 206A, 206B, 208A, 208B are surface mount features that can be used to mount electric components to the printed circuit board 200. For example, the package-side contact pad arrays 206A, 206B can be used to form a ball grid array (BGA) connection between the printed circuit board 200 and an integrated circuit package and the memory-side contact pad arrays 208A, 208B can used to form a BGA connection between the printed circuit board 200 and memory dies that are to communicate with the integrated circuit package. In FIG. 2, the package-side contact pad arrays 206A, 206B (e.g., the contact pads that receive the integrated circuit package, etc.) have a different arrangement from the memory-side contact pad arrays 208A, 208B (e.g., the contact pads that receive the memory dies, etc.).

In FIG. 2 the memory-side contact pad arrays 208A, 208B are configured according to a first JEDEC standard (e.g., a JEDEC standard associated with memory dies, etc.) and the package-side contact pad arrays 206A, 206B are configured according to a second JEDEC standard (e.g., a JEDEC standard associated with package substrates, etc.). In FIG. 2, the memory-side contact pad arrays 208A, 208B are longer in the X direction than the package-side contact pad arrays 206A, 206B. Additionally in FIG. 2, the package-side contact pad arrays 206A, 206B are not longitudinally aligned with the memory-side contact pad arrays 208A, 208B, respectively. That is, the memory-side contact pad arrays 208A, 208B include contact pads that are not longitudinally aligned with corresponding pads of the package-side contact pad arrays 206A, 206B. Additionally, the package-side contact pad arrays 206A, 206B have a different arrangement than the memory-side contact pad arrays 208A, 208B. Particularly, the contact pads of the package-side contact pad arrays 206A, 206B are arranged in a grid with alternating offset columns, and the memory-side contact pad arrays 208A, 208B are arranged in an evenly distributed grid.

The prior trace configuration 202 includes a plurality of traces 210 that extend through the printed circuit board 200 and electrically couple the contact pads of the first package-side contact pad array 206A and the second package-side contact pad array 206B to the first memory-side contact pad array 208A and the second memory-side contact pad array 208B, respectively. In FIG. 2, the different arrangement of the contact pads in the different contact pad arrays 206A, 206B, 208A, 208B (i.e., the different footprint and functional ordering of the package-side contact pad arrays 206A, 206B compared to that of the memory-side contact pad arrays 208A, 208B, etc.) causes the traces 210 of the trace configuration to fanout, swizzle (e.g., mix, etc.) and un-swizzle (e.g., unmix, etc.) in the region between the contact pad arrays 206A, 206B, 208A, 208B. That is, the traces of the prior trace configuration 202 extend laterally outward from the contact pad arrays 206A, 206B, 208A, 208B. The fanout and swizzling increases the packaging space of the prior trace configuration 202 and thereby the overall size requirement of the printed circuit board 200. Furthermore, the swizzling and unswizzling of the traces of the prior trace configuration 202 (e.g., the curving and directional changes of the traces of the prior trace configuration 202, etc.) increases the required distance between the contact pad arrays 206A, 206B, 208A, 208B (e.g., the distance between the integrated circuit package received by the package-side contact pad arrays 206A, 206B and the memory dies received by the memory-side contact pad arrays 208A, 208B, etc.). In FIG. 2, the portion of the printed circuit board 200 between the different contact pad arrays 206A, 206B, 208A, 208B that includes the traces 210 has a longitudinal length 212. That is, the package-side contact pad arrays 206A, 206B are spaced from the memory-side contact pad arrays 208A, 208B by the longitudinal length 212. The longitudinal length 212 is between 7 millimeters and 10 millimeters on prior printed circuit boards. This distance is needed to provide sufficient space for the unswizzling of the traces to electrical couple corresponding contact pads between the different contact pad arrays 206A, 206B, 208A, 208B.

It should be appreciated that the printed circuit board 200 can include additional contact pads that receive an integrated circuit package in addition to the contact pads of the package-side contact pad arrays 206A, 206B. In such examples, the package-side contact pad arrays 206A, 206B correspond to the contact pads that receive the integrated circuit package that are coupled to the traces 210. It should be appreciated that the prior trace configuration 202 of the printed circuit board 200 includes further traces in addition to the ones depicted in FIG. 2. That is, the quantity of traces of the trace configuration 202 has been reduced for visual clarity. Additionally, the trace configuration 202 includes additional traces disposed in lower layers in the printed circuit board 200, which are similarly fanned out and swizzled as the traces depicted in FIG. 2.

FIG. 3 is a schematic diagram of the example printed circuit board 102 of FIG. 1 including an example trace configuration 300 constructed in accordance with teachings of this disclosure. In the illustrated example of FIG. 3, the trace configuration 300 includes example traces 303. In the illustrated example of FIG. 3, the printed circuit board 102 includes an example first package-side contact pad array 304A, an example second package-side contact pad array 304B, an example first memory-side contact pad array 306A, and an example second memory-side contact pad array 306B. In the illustrated example of FIG. 3, the package-side contact pad arrays 304A, 304B are configured to mount (e.g., receive, support, etc.) the integrated circuit package 104 of FIG., the first memory-side contact pad array 306A is configured to mount (e.g., receive, support, etc.) the first memory die 106A of FIG. 1, and the second memory-side contact pad array 306B is configured to mount (e.g., receive, support, etc.) the second memory die 106B of FIG. 3. In other examples, the contact pad arrays 306A, 306B can be configured to receive another component to be mounted to the printed circuit board 102 (e.g., an input/output device, another interface, etc.).

In the illustrated example of FIG. 3, the contact pad arrays 304A, 304B, 306A, 306B have a matching arrangement (e.g., a same arrangement, a corresponding arrangement, a symmetric arrangement, etc.). That is, in the illustrated example of FIG. 3, each of the contact pad arrays 304A, 304B, 306A, 306B have a same footprint. Further, in this example, the functional ordering of the contact pads in the package-side contact pad arrays 304A, 304B correspond to the functional ordering of the corresponding contact pads in the corresponding memory-side contact pad arrays 306A, 306B. In the illustrated example of FIG. 3, the first package-side contact pad array 304A is longitudinally aligned with the first memory-side contact pad array 306A and the second package-side contact pad array 304B is longitudinally aligned (e.g., along the X axis) with the second memory-side contact pad array 306B. In other examples, the contact pad arrays 304A, 304B, 306A, 306B can have another arrangement. In some examples, the first package-side contact pad array 304A and the first memory-side contact pad array 306A can have a first arrangement and the second package-side contact pad array 304B and the second memory-side contact pad array 306B can have a second arrangement different than the first arrangement.

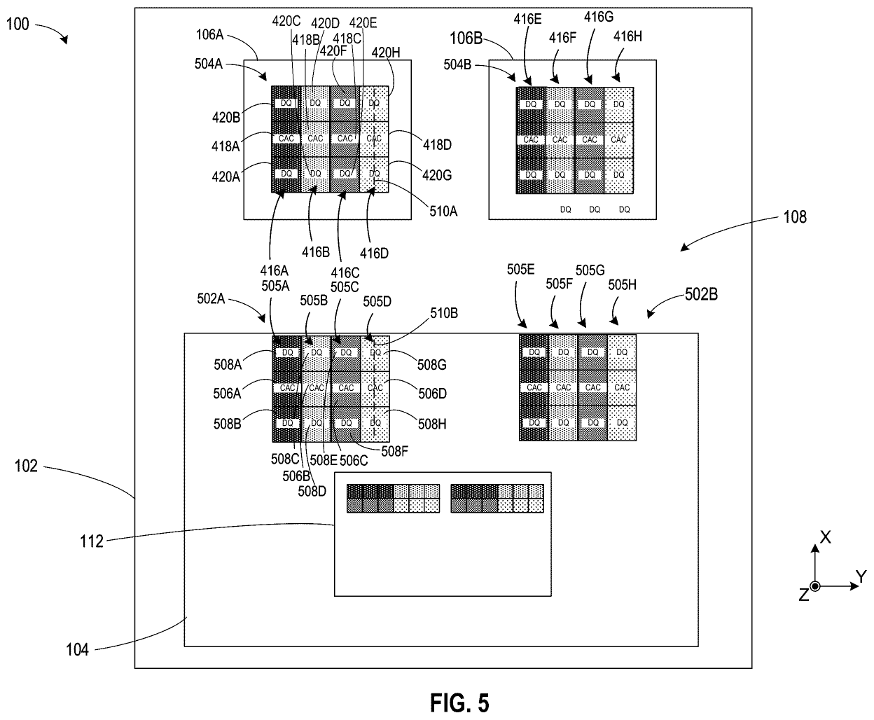

The longitudinal alignment of the contact pad arrays 304A, 304B, 306A, 306B, along with the matching functional ordering of the contact pads in the different contact pad arrays 304A, 304B, facilitates the interconnection of the contact pad arrays 304A, 304B, 306A, 306B. Specifically, in the illustrated example of FIG. 3, the mapping of the contact pad arrays 304A, 304B, 306A, 306B causes a same type of contact pad (e.g., contact pads associated with the a data bit (e.g., data contact pads), contact pads associated with a command/address bit (e.g., address contact pads), etc.) of the package-side contact pad arrays 304A, 304B to be aligned with a same type of contact pad of the memory-side contact pad arrays 306A, 306B. For example, each contact pad of the package-side contact pad arrays 304A, 304B associated with a data bit is longitudinally aligned with a corresponding contact pad of the memory-side contact pad arrays 306A, 306B associated with a data bit (e.g., a contact pad associated with a same data bit, a contact pad associated with a different data bit, etc.). More particularly, as shown in the illustrated example, each contact pad (of a given functional type) within the memory-side contact pad arrays 306A, 306B is electrically coupled (via a respective one of the traces 303) to a corresponding contact pad (of the same functional type) in the package-side contact pad arrays 304A, 304B, with both contact pads being longitudinally aligned. Longitudinally aligning each corresponding (e.g., electrically coupled) pair of contact pads along the same axis in this manner enables the traces 303 that connect the respective pairs of contact pads to extend parallel to one another along the same axis as discussed further below. An example layout of contact pads associated with the memory-side contact pad arrays 306A, 306B is described in additional detail below in conjunction with FIG. 5.

In the illustrated example of FIG. 3, the printed circuit board includes an example first region 308 defined by the footprint of the package-side contact pads 304A, 304B (e.g., longitudinally aligned with the integrated circuit package 104, etc.), an example second region 310 that is defined by the footprint of the memory-side contact pad arrays 306A, 306B, and an example third region 312 that is longitudinally between the regions 308, 310. In the illustrated example of FIG. 3, the regions 308, 310, 312 are laterally bound by the outboard ends (e.g., the ends of contact pad arrays 304A, 304B, 306A, 306B adjacent to an example first side 314A and an example second side 314B) of the printed circuit board 102. In the illustrated example of FIG. 3, the boundaries regions 308, 310, 312 are spaced for visual clarity. In other examples, the boundaries of the regions 308, 310, 312 are overlayed.

As noted above, in the illustrated example, the matching and longitudinally aligned arrangements of contact pad arrays 304A, 304B, 306A, 306B enable the traces 303 to extend directly between the contact pads of the contact pad arrays 304A, 304B, 306A, 306B. That is, the traces 303 do not swizzle and unswizzle between the contact pad arrays 304A, 304B, 306A, 306B. In the illustrated example of FIG. 3, the traces 303 of the trace configuration 300 are parallel in the third region 312. In the illustrated example of FIG. 3, the traces 303 are parallel to the sides 314A, 314B of the printed circuit board 102. In other examples, the traces 303 are not parallel to (e.g., form an acute angle with, form an obtuse angle with, etc.) the sides 314A, 314B (e.g., if contact pad arrays 304A, 304B, 306A, 306B are not laterally aligned, etc.). In the illustrated example of FIG. 3, the traces 303 do not fanout. That is, the traces 303 do not extend laterally outside of the third region 312 (e.g., laterally outboard of the contact pad arrays 304A, 304B, 306A, 306B, etc.).

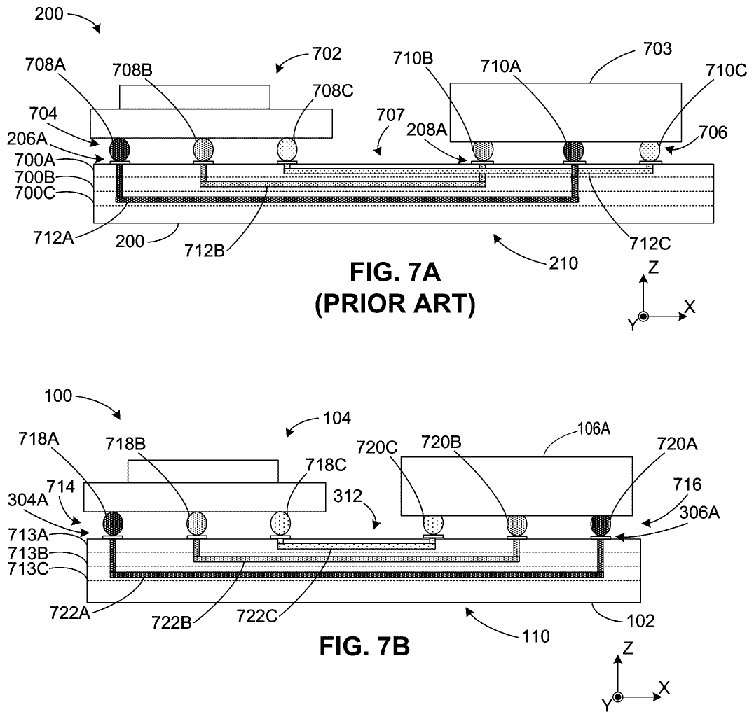

The matching arrangements (e.g. the same arrangements, etc.) of contact pad arrays 304A, 304B, 306A, 306B enable the direct connection via the traces 303, which reduces the size (e.g., the vertical length, the lateral length, etc.) of the third region 312 when compared to prior trace configurations, such as the trace configuration 202 of FIG. 2. In the illustrated example of FIG. 3, the third region 312 has an example length 316. That is, the package-side contact pad arrays 304A, 304B are spaced from the memory-side contact pad arrays 306A, 306B by the length 316. The trace configuration 300 of FIG. 3 enables the length 316 to be significantly less than the 7 millimeters (e.g., less than 5 millimeters, less than 3 millimeters, less than 2 millimeters, etc.), which reduces the longitudinal length of the printed circuit board 102 when compared to the prior printed circuit board 200 of FIG. 2. As a result, in some examples, the length 316 is as much as or more than 3.5 times smaller than the length 212. In other words, the region of the printed circuit board 102 between the different contact pad arrays 304A, 304B, 306A, 306B that include the traces 303 is at least 3.5 times smaller than the region of the printed circuit board 102 occupied by the traces in the printed circuit board 200. It should also be appreciated that the printed circuit board 102 can include additional contact pads that receive an integrated circuit package in addition to the contact pads of the contact pad arrays 304A, 304B. In such examples, the package-side contact pad arrays 304A, 304B correspond to the contact pads that receive the integrated circuit package (e.g., the integrated circuit package 104 of FIG. 1, etc.) and are coupled to the traces 303. It should be appreciated that the example trace configuration 300 of the printed circuit board 102 includes further traces in addition to the ones depicted in the illustrated example FIG. 3. That is, the quantity of traces of the trace configuration 300 has been reduced for visual clarity. Additionally, the trace configuration 300 includes additional traces disposed in lower layers in the printed circuit board 102, which can be similarly parallel to one another and the traces 303. The layers of the printed circuit board 102 and example traces disposed therein are described below in conjunction with FIG. 7B.

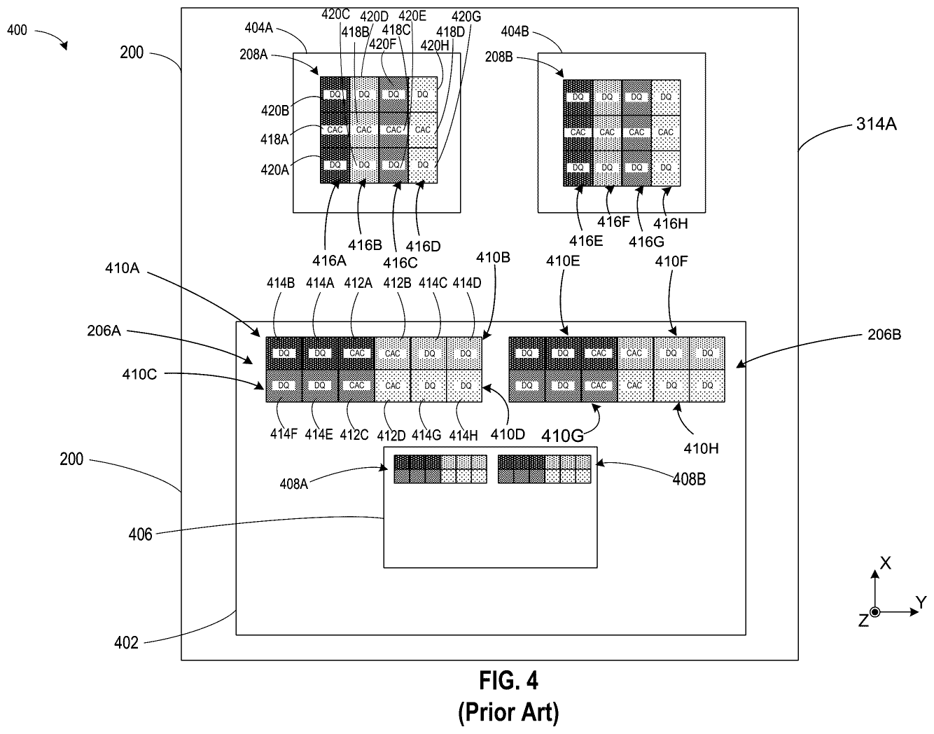

FIG. 4 is a schematic cross-sectional side diagram of the prior printed circuit board assembly 400 including the known printed circuit board of 200 of FIG. 2. In FIG. 4, the printed circuit board assembly 400 includes an integrated circuit package 402, a first memory die 404A, and a second memory die 404B. In FIG. 4, the integrated circuit package 402 is mounted to the printed circuit board 102 via the package-side contact pad arrays 206A, 206B. In FIG. 4, the first memory die 404A is mounted to the printed circuit board 102 via the first memory-side contact pad array 208A, and the second memory die 404B is mounted to the printed circuit board 102 via the second memory-side contact pad array 208B. In FIG. 4, the integrated circuit package 402 includes a die 406, which includes a fifth contact pad array 408A and a sixth contact pad array 408B. As used herein, the term “address contact pads” refers to both command contact pads and address contact pads. In FIGS. 4-6, the abbreviation “DQ” is indicative of data contact pads and the abbreviation “CAC” is indicative of command, address, and clock contact pads.

In FIG. 4, the first package-side contact pad array 206A includes a first package-side contact pad set 410A, which includes a first package-side address contact pad 412A, a first package-side data contact pad 414A, and a second package-side data contact pad 414B. In FIG. 4, the first package-side contact pad array 206A includes a second package-side contact pad set 410B, which includes a second package-side address contact pad 412B, a third package-side data contact pad 414C, and a fourth package-side data contact pad 414D. In FIG. 4, the first package-side contact pad array 206A includes a third package-side contact pad set 410C, which includes a third package-side address contact pad 412C, a fifth package-side data contact pad 414E, and a sixth package-side data contact pad 414F. In FIG. 4, the first package-side contact pad array 206A includes a fourth package-side contact pad set 410D, which includes a fourth package-side address contact pad 412D, a seventh package-side data contact pad 414G, and an eighth package-side data contact pad 414H. In FIG. 4, the second package-side contact pad array 206B includes a fifth package-side contact pad set 410E, a sixth package-side contact pad set 410F, a seventh package-side contact pad set 410G, and an eighth package-side contact pad set 410H, which include the same configuration of package-side data and address contact pads as the first package-side contact pad set 410A, the second package-side contact pad set 410B, the third package-side contact pad set 410C, and the fourth package-side contact pad set 410D, respectively.

In FIG. 4, the first memory-side contact pad array 208A includes a first memory-side contact pad set 416A, which includes a first memory-side address contact pad 418A, a first memory-side data contact pad 420A, and a second memory-side data contact pad 420B. In FIG. 4, the memory-side contact pad array 208A includes a second memory-side contact pad set 416B, which includes a second memory-side address contact pad 418B, a third memory-side data contact pad 420C, and a fourth memory-side data contact pad 420D. In FIG. 4, the memory-side contact pad array 208A includes a third memory-side contact pad set 416C, which includes a third memory-side address contact pad 418C, a fifth memory-side data contact pad 420E, and a sixth memory-side data contact pad 420F. In FIG. 4, the memory-side contact pad array 208A includes a fourth memory-side contact pad set 416D, which includes a fourth memory-side address contact pad 418D, a seventh memory-side data contact pad 420G, and an eighth memory-side data contact pad 420H. In FIG. 4, the second memory-side contact pad array 208B includes a fifth memory-side contact pad set 416E, a sixth memory-side contact pad set 416F, a seventh memory-side contact pad set 416G, and an eighth memory-side contact pad set 416H, which include the same configurations of memory-side data and address contact pads as the first memory-side contact pad set 416A, the second memory-side contact pad set 416B, the third memory-side contact pad set 416C, and the fourth memory-side contact pad set 416D, respectively.

It should be appreciated that the contact pad arrays 206A, 206B, 208A, 208B can include additional contact pads than the contact pads depicted in FIG. 4. For example, if each of the contact pad sets 410A, 410B, 410C, 410D, 410E, 410F, 410G, 410H, 416A, 416B, 416C, 416D, 416E, 416F, 416G, 416H corresponds to a byte, each of the contact pad sets 410A, 410B, 410C, 410D, 410E, 410F, 410G, 410H, 416A, 416B, 416C, 416D, 416E, 416F, 416G, 416H can include 8 contact pads (e.g., 5 in addition to those depicted in FIG. 4, etc.). Additionally, some or all of the contact pad arrays 206A, 206B, 208A, 208B can include additional sets of contact pads.

To couple the contact pads of the first memory-side contact pad array 208A to the first package-side contact pad array 206A, each of the contact pads of the first memory-side contact pad array 208A are electrically coupled to a corresponding contact pad of the first memory-side contact pad array 208A via a trace. Particularly, each contact pad of the first package-side contact pad set 410A is coupled to a corresponding contact pad of the first memory-side contact pad set 416A via a trace (e.g., the first package-side address contact pad 412A is coupled via a trace to the first memory-side address contact pad 418A, the first package-side data contact pad 414A is coupled via a trace to the first memory-side data contact pad 420A, the second package-side data contact pad 414B is coupled via a trace to the second memory-side data contact pad 420B, etc.). Each contact pad of the second package-side contact pad set 410B is coupled to a corresponding contact pad of the second memory-side contact pad set 416B via a trace (e.g., the second package-side address contact pad 412B is coupled via a trace to the second memory-side address contact pad 418B, the third package-side data contact pad 414C is coupled via a trace to the third memory-side data contact pad 420C, the fourth package-side data contact pad 414D is coupled via a trace to the fourth memory-side data contact pad 420D, etc.). Each contact pad of the third package-side contact pad set 410C is coupled to a corresponding contact pad of the third memory-side contact pad set 416C via a trace (e.g., the third package-side address contact pad 412C is coupled via a trace to the third memory-side address contact pad 418C, the fifth package-side data contact pad 414E is coupled via a trace to the fifth memory-side data contact pad 420E, the sixth package-side data contact pad 414F is coupled via a trace to the sixth memory-side data contact pad 420F, etc.). Each contact pad of the fourth package-side contact pad set 410D is coupled to a corresponding contact pad of the fourth memory-side contact pad set 416D via a trace (e.g., the fourth package-side address contact pad 412D is coupled via a trace to the fourth memory-side address contact pad 418D, the seventh package-side data contact pad 414G is coupled via a trace to the seventh memory-side data contact pad 420G, the eighth package-side data contact pad 414H is coupled via a trace to the eighth memory-side data contact pad 420H, etc.). The traces coupling the contact pads of the contact pad arrays 206A, 206B, 208A, 208B are not depicted in FIG. 4 for visual clarity. Prior trace configurations that can be used to implement the traces that couple the contact pad arrays 206A, 206B, 208A, 208B are depicted in FIG. 2.

In FIG. 4, the package-side contact pad arrays 206A, 206B have different arrangements than the memory-side contact pad arrays 208A, 208B, which prevents longitudinal alignments between corresponding ones of the contact pads. In FIG. 4, the contact pads of the package-side contact pad arrays 206A, 206B have a two-dimensional distribution that is a 2×6 grid (i.e., two rows of six contact pads, etc.) and the contact pads of the memory-side contact pad arrays 208A, 208B have a two-dimensional distribution that is a 3×4 grid (i.e., three rows of four contact pads, etc.). Furthermore, the package-side contact pad sets 410A, 410B, 410C, 410D are aligned along the lateral axis (e.g., the Y axis shown in FIG. 4) and the memory-side contact pad sets 416A, 416B, 416C, 416D are aligned along the longitudinal axis (e.g., the X axis shown in FIG. 4). As such, in the prior printed circuit board assembly 400 of FIG. 4, the package-side address contact pads 412A, 412B, 412C, 412D are not longitudinally aligned with the memory-side address contact pads 418A, 418B, 418C, 418D, and the package-side data contact pads 414A, 414B, 414C, 414D, 414E, 414F, 414G, 414H are not longitudinally aligned with the memory-side data contact pads 420A, 420B, 420C, 420D, 420E, 420F, 420G, 420H. The different arrangements (e.g., footprints, 2D distributions, and the functional orderings, etc.) of the package-side contact pad arrays 206A, 206B and the memory-side contact pad arrays 208A, 208B and the associated lack of alignment between corresponding ones of the address contact pads 412A, 412B, 412C, 412D, 418A, 418B, 418C, 418D and corresponding ones of the data contact pads 414A, 414B, 414C, 414D, 414E, 414F, 414G, 414H, 420A, 420B, 420C, 420D, 420E, 420F, 420G, 420H causes the traces connecting the contact pad arrays 206A, 206B, 208A, 208B to fanout, swizzle, and unswizzle.

The second package-side contact pad array 206B can be electrically coupled to the second memory-side contact pad array 208B in a manner similar to the coupling of the first package-side contact pad array 206A to the first memory-side contact pad array 208A. That is, the traces (1) coupling the contact pads of the fifth package-side contact pad set 410E to the fifth memory-side contact pad set 416E, (2) coupling the contact pads of the sixth package-side contact pad set 410F to the sixth memory-side contact pad set 416F, (3) coupling the contact pads of the seventh package-side contact pad set 410G to the seventh memory-side contact pad set 416G, and (4) coupling the contact pads of the seventh package-side contact pad set 410G to the seventh memory-side contact pad set 416G similarly fanout, swizzle, and unswizzle as the traces coupling the first package-side contact pad array 206A to the first memory-side contact pad array 208A.

FIG. 5 is a schematic cross-sectional side diagram of the example printed circuit board assembly 100 of FIG. 1. In the illustrated example of FIG. 5, the printed circuit board assembly 100 includes the printed circuit board 102 of FIG. 1, the integrated circuit package 104 of FIG. 1, and the memory dies 106A, 106B of FIG. 1. In the illustrated example of FIG. 5, the integrated circuit package 104 is mounted to the printed circuit board 102 via an example first package-side contact pad array 502A and an example second package-side contact pad array 502B. In the illustrated example of FIG. 5, the first memory die 106A is mounted to the printed circuit board 102 via an example first memory-side contact pad array 504A, and an example fourth memory die 106B is mounted to the printed circuit board 102 via the second memory-side contact pad array 504B. In the illustrated example of FIG. 5, the memory-side contact pad arrays 504A, 504B has the same arrangement as the memory-side contact pad arrays 208A, 208B of FIG. 4 (e.g., the memory-side contact pad arrays 504A, 504B include the memory-side contact pads sets 416A, 416B, 416C, 416D, etc.).

In the illustrated example of FIG. 5, the first package-side contact pad array 502A includes a first package-side contact pad set 505A, which includes an example first package-side address contact pad 506A, an example first package-side data contact pad 508A, and an example second package-side contact pad 508B. In the illustrated example of FIG. 5, the first package-side contact pad array 206A includes an example second package-side contact pad set 505B, which includes an example second package-side address contact pad 506B, an example third package-side data contact pad 508C, and an example fourth package-side contact pad 508D. In the illustrated example of FIG. 5, the first package-side contact pad array 502A includes an example third package-side contact pad set 505C, which includes an example third package-side address contact pad 506C, an example fifth package-side data contact pad 508E, and an example sixth package-side data contact pad 508F. In the illustrated example of FIG. 5, the first package-side contact pad array 502A includes an example fourth package-side contact pad set 505D, which includes an example fourth package-side address contact pad 506D, an example seventh package-side data contact pad 508G, and an example eighth package-side data contact pad 508H. In the illustrated example of FIG. 5, the second package-side contact pad array 206B includes an example fifth package-side contact pad set 505E, an example sixth package-side contact pad set 505F, an example seventh package-side contact pad set 505G, and an example eight package-side contact pad set 505H, which have the same arrangements of package-side data and address contact pads as the first package-side contact pad set 505A, the second package-side contact pad set 505B, the third package-side contact pad set 505C, and the fourth package-side contact pad set 505D, respectively.

It should be appreciated that the contact pad arrays 502A, 502B, 504A, 504B can include additional contact pads than the contact pads depicted in the illustrated example of FIG. 5. For example, if each of the contact pad sets 505A, 505B, 505C, 505E, 505E, 505F, 505G, 505H, 416A, 416B, 416C, 416D, 416E, 416F, 416G, 416H corresponds to a byte, each of the sets of the contact pad sets 505A, 505B, 505C, 505E, 505E, 505F, 505G, 505H, 416A, 416B, 416C, 416D, 416E, 416F, 416G, 416H can include 8 contact pads (e.g., 5 in addition to those depicted in the illustrated example of FIG. 5, etc.). Additionally, some or all of the contact pad arrays 502A, 502B, 504A, 504B can include additional sets of contact pads.

To couple the contact pads of the first memory-side contact pad array 504A to the first package-side contact pad array 502A, the contact pads of the first package-side contact pad array 502A are electrically coupled to a corresponding contact pad of the first memory-side contact pad array 504A via one or more traces. For example, each contact pad of the first package-side contact pad set 505A is coupled to a corresponding contact pad of the first memory-side contact pad set 416A via a trace (e.g., the first package-side address contact pad 506A is coupled via a trace to the first memory-side address contact pad 418A, the first package-side data contact pad 508A is coupled via a trace to the first memory-side data contact pad 420A, the second package-side data contact pad 508B is coupled via a trace to the second memory-side data contact pad 420B, etc.). In some examples, each contact pad of the second package-side contact pad set 505B is coupled to a corresponding contact pad of the second memory-side contact pad set 416B via a trace (e.g., the second package-side address contact pad 506B is coupled via a trace to the second memory-side address contact pad 418B, the third package-side data contact pad 508C is coupled via a trace to the third memory-side data contact pad 420C, the fourth package-side data contact pad 508D is coupled via a trace to the fourth memory-side data contact pad 420D, etc.). In some examples, each contact pad of the third package-side contact pad set 505C is coupled to a corresponding contact pad of the third memory-side contact pad set 416C via a trace (e.g., the third package-side address contact pad 506C is coupled via a trace to the third memory-side address contact pad 418C, the fifth package-side data contact pad 508E is coupled via a trace to the fifth memory-side data contact pad 420E, the sixth package-side data contact pad 508F is coupled via a trace to the sixth memory-side data contact pad 420F, etc.). In some examples, each contact pad of the fourth package-side contact pad set 505D is coupled to a corresponding contact pad of the fourth memory-side contact pad set 416D via a trace (e.g., the fourth package-side address contact pad 506D is coupled via a trace to the fourth memory-side address contact pad 418D, the seventh package-side data contact pad 508G is coupled via a trace to the seventh memory-side data contact pad 420G, the eighth package-side data contact pad 508H is coupled via a trace to the eighth memory-side data contact pad 420H, etc.). The traces coupling the contact pads of the contact pad arrays 206A, 206B, 208A, 208B are not depicted in the illustrated example of FIG. 5 for visual clarity.

In the illustrated example FIG. 5, the package-side contact pad arrays 502A, 502B have a same arrangement as the memory-side contact pad arrays 504A, 504B. In the illustrated example of FIG. 5, the contact pads of the package-side contact pad arrays 502A, 502B and the contact pads of the memory-side contact pad arrays 504A, 504B are arranged in a 3×4 grid two-dimensional distribution, have the same functional ordering, and the same footprint. In other examples, the contact pads of the contact pad arrays 502A, 502B, 504A, 504B can have a different arrangement than what is shown but that is the same as between the different contact pad arrays 502A, 502B, 504A, 504B. For instance, in some examples, the contact pad arrays 502A, 502B, 504A, 504B can have an arrangement corresponding to a 2×6 grid two-dimensional distribution of the package-side contact pad arrays 206A, 206B of FIGS. 2 and 4. In the illustrated example of FIG. 5, the memory-side contact pad sets 416A, 416B, 416C, 416D are arranged in the same order as the package-side contact pad sets 505A, 505B, 505C, 505D along the lateral axis. In the illustrated example of FIG. 5, the memory-side contact pad sets 416A, 416B, 416C, 416D, and the package-side contact pad sets 505A, 505B, 505C, 505D have the same arrangement (e.g., ordering, etc.) of data contact pads (e.g., the specific ordering of the data contact pads 420A, 420B and the address contact pad 418A in the first memory-side contact pad array 504A, etc.). As such, in the illustrated example of FIG. 5, each corresponding pair of contact pads (e.g., the address contact pads 506A, 418A, the address contact pads 506B, 418B, the address contact pads 506C, 418C, the address contact pads 506D, 418D, the data contact pads 508A, 420A, the data contact pads 508B, 420B, the data contact pads 508C, 420C, the data contact pads 508D, 420D, the data contact pads 508E, 420E, the data contact pads 508F, 420F, the data contact pads 508G, 420G, the data contact pads 508H, 420H, etc.) is longitudinally aligned such that a trace connecting the corresponding pairs of contact pads can extend in a substantially straight line along the longitudinal axis.

In the illustrated example of FIG. 5, each of the memory-side contact pad sets 410A, 410B, 410C, 410D, and the package-side contact pad sets 505A, 505B, 505C, 505D are disposed along parallel longitudinal lines. In the illustrated example of FIG. 5, each corresponding pair of the memory-side contact pad sets 410A, 410B, 410C, 410D and the package-side contact pad sets 505A, 505B, 505C, 505D are disposed along colinear lines. For example, in the illustrated example of FIG. 5, the fourth memory-side contact pad set 416D is disposed along an example first line 510A and the fourth package-side contact pad set is disposed along an example second line 510B. In the illustrated example of FIG. 5, the first line 510A, 510B are parallel and colinear. In the illustrated example of FIG. 5, the lines 510A, 510B are parallel to the sides 314A, 314B. In other examples, the first line 510A, 510B are parallel and not colinear. In other examples, the lines 510A, 510B and/or the lines defining other ones of the contact pad sets 410A, 410B, 410C, 505A, 505B, 505C are parallel and not disposed along the longitudinal axis (e.g., not parallel to the sides 314A, 314B, etc.).

Additionally, in the illustrated example of FIG. 4, the memory-side contact pad sets 410A, 410B, 410C, 410D, and the package-side contact pad sets 505A, 505B, 505C, 505D are mirrored about the region 108, such that the innermost pairs of the pads (e.g., the data contact pads 508A, 420A, the data contact pads 508C, 420C, etc.) are to be coupled via traces and the outermost pairs of pads (e.g., the data contact pads 508B, 420B, the data contact pads 508D, 420D, etc.) are similarly coupled via traces. That is, the function orderings of the memory-side contact pad sets 410A, 410B, 410C, 410D are symmetric (e.g., mirrored, etc.) to the functional ordering of the package-side contact pad sets 505A, 505B, 505C, 505D relative to the region 108 (e.g., the third portion 312 of FIG. 3, etc.). The relationship between the trace configurations and the ordering of pad is described below in additional detail in conjunction with FIG. 7B.

In other examples, the contact pad arrays 502A, 502B, 504A, 504B do not have the same lateral ordering of sets (e.g., the leftmost one of the package-side contact pad array 502A does not corresponding to the leftmost one of the first memory-side contact pad array 504A, etc.). In some such examples, the integrated circuit package 104 can include a memory controller that enables individual sets of contact pads to be swapped (e.g., byte swapping, the memory controller can digitally swap the inputs to the first memory-side contact pad set 416A with the second memory-side contact pad set 416B, etc.). Additionally or alternatively, the data contact pads and/or the assembly contact pads can have different arrangements in different ones of the contact pad sets 416A, 416B, 416C, 416D, 505A, 505B, 505C, 505D. In some such examples, the integrated circuit package 104 can include a memory controller to swap the inputs to individual contact pads (e.g., bit swapping, the memory controller can digitally swap the inputs to the first memory-side data contact pad 420A and the second memory-side data contact pad 420B, the memory controller can digitally swap the inputs of the first memory-side data contact pad 420A and the third memory-side data contact pad 420C, etc.). It should be appreciated that some memory controller systems support bit swapping within bytes and byte swapping within 16× channels.

The same arrangements of the package-side contact pad arrays 502A, 502B and the memory-side contact pad arrays 504A, 504B and the associated alignment between corresponding ones of the address contact pads 506A, 506B, 506C, 506D, 418A, 418B, 418C, 418D and corresponding ones of the data contact pads 508A, 508B, 508C, 508D, 508E, 508F, 508G, 508H, 420A, 420B, 420C, 420D, 420E, 420F, 420G, 420H causes the traces connecting the contact pad arrays 502A, 502B, 504A, 504B to extend directly therebetween without fanning out, swizzling, and/or unswizzling. For example, the arrangement of the contact pad arrays 502A, 504A enables the traces connecting the contact pads of the contact pad arrays 502A, 504A to directly (e.g., via a straight line along the axial axis, etc.) route between corresponding pads of the contact pad arrays 502A, 504A. For example, the contact pad arrays 502A, 504A can be coupled via traces having the trace configuration 300 of FIG. 3.

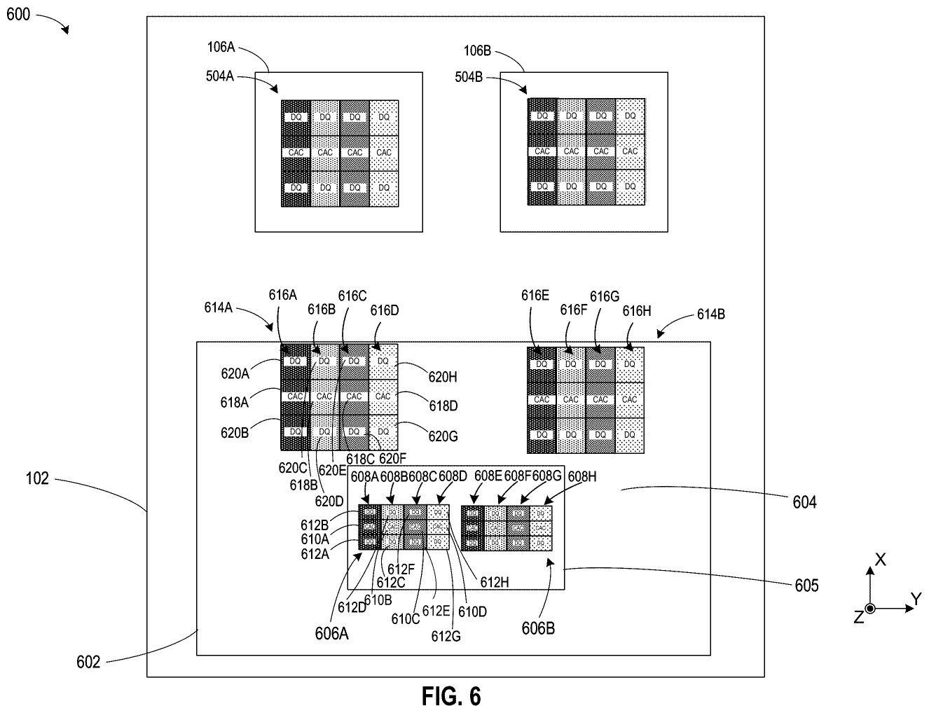

FIG. 6 is a schematic diagram of a printed circuit board assembly 600 implemented in accordance with teachings of this disclosure. In the illustrated example of FIG. 6, the printed circuit board assembly 600 includes the printed circuit board 102 of FIG. 1, an example integrated circuit package 602, and the memory dies 106A, 106B of FIG. 1. The integrated circuit package 602 is similar to the integrated circuit package 104, except that the integrated circuit package 602 includes an example package substrate 604 and an example die 605. In the illustrated example of FIG. 6, the die 605 is mounted on the package substrate 604 via an example first die-side contact pad array 606A and an example second die-side contact pad array 606B.

In the illustrated example of FIG. 6, the first die-side contact pad array 606A includes an example first die-side contact pad set 608A, which includes an example first die-side address contact pad 610A, an example first die-side data contact pad 612A, and an example second die-side contact pad 612B. In the illustrated example of FIG. 6, the first die-side contact pad array 606A includes an example second die-side contact pad set 608B, which includes an example second die-side address contact pad 610B, an example third die-side data contact pad 612C, and an example fourth die-side contact pad 612D. In the illustrated example of FIG. 6, the first die-side contact pad array 606A includes an example third die-side contact pad set 608C, which includes an example third die-side address contact pad 610C, an example fifth die-side data contact pad 612E, and an example sixth die-side contact pad 612F. In the illustrated example of FIG. 6, the first die-side contact pad array 606A includes an example fourth die-side contact pad set 608D, which includes an example fourth die-side address contact pad 610D, an example seventh die-side data contact pad 612G, and an example eighth die-side contact pad 612H. In the illustrated example of FIG. 6, the second die-side contact pad array 606B includes an example fifth die-side contact pad set 608E, an example sixth die-side contact pad set 608F, an example seventh die-side contact pad set 608G, and an example eight die-side contact pad set 608H, which include the same functional ordering of die-side data and address contact pads as the first die-side contact pad set 608A, the second die-side contact pad set 608B, the third die-side contact pad set 608C, and the fourth die-side contact pad set 608D, respectively. The die 605 includes a plurality of contact pads (not illustrated) that are electrically coupled to the die-side contact pad arrays 606A, 606B via a plurality of traces. In some such examples, the die-side contact pad arrays 606A, 606B can form a BGA connection with the die 605. Thus, in some examples, the die-side contact pad arrays 606A, 606B are on a first side of the package substrate 604 that is facing away from the printed circuit board 102 and is supporting the die 605.

In the illustrated example of FIG. 6, the package substrate 604 includes an example first PCB-side contact pad array 614A and an example second PCB-side contact pad array 614B. In this example, the PCB-side contact pad arrays 614A, 614B are on a second side of the package substrate 604 that is facing towards the printed circuit board 102. In the illustrated example of FIG. 6, the first PCB-side contact pad array 614A includes a first PCB-side contact pad set 616A, which includes an example first PCB-side address contact pad 618A, an example first PCB-side data contact pad 620A, and an example second PCB-side contact pad 620B. In the illustrated example of FIG. 6, the first PCB-side contact pad array 614A includes an example second PCB-side contact pad set 616B, which includes an example second PCB-side address contact pad 618B, an example third PCB-side data contact pad 620C, and an example fourth PCB-side contact pad 620D. In the illustrated example of FIG. 6, the first PCB-side contact pad array 614A includes an example third PCB-side contact pad set 616C, which includes an example third PCB-side address contact pad 618C, an example fifth PCB-side data contact pad 620E, and an example sixth PCB-side data contact pad 620F. In the illustrated example of FIG. 6, the first PCB-side contact pad array 614A includes an example fourth PCB-side contact pad set 616D, which includes an example fourth PCB-side address contact pad 618D, an example seventh PCB-side data contact pad 620G, and an example eighth PCB-side contact pad 620H. In the illustrated example of FIG. 6, the second PCB-side contact pad array 614B includes an example fifth PCB-side contact pad set 616E, an example sixth PCB-side contact pad set 616F, an example seventh PCB-side contact pad set 616G, and an example eight PCB-side contact pad set 616H which include the same configuration of PCB-side data and address contact pads as the first PCB-side contact pad set 616A, the second PCB-side contact pad set 616B, the third PCB-side contact pad set 616C, and the fourth PCB-side contact pad set 616D, respectively.

In some examples, the PCB-side contact pad arrays 614A, 614B can form a BGA connection with corresponding contact pads on the printed circuit board 102. For example, the PCB-side contact pad arrays 614A, 614B can be electrically coupled via a plurality of balls coupling each of the contact pads of the PCB-side contact pad arrays 614A, 614B to a corresponding contact pad of a contact pad array on the printed circuit board 102 (e.g., the package-side contact pad arrays 502A, 502B, etc.).

It should be appreciated that the contact pad arrays 606A, 606B, 614A, 614B can include additional contact pads than the contact pads depicted in the illustrated example of FIG. 6. For example, if each of the contact pad sets 608A, 608B, 608C, 608D, 608E, 608F, 608G, 608H, 616A, 616B, 616C, 616D, 616E, 616G, 616H corresponds to a byte, each of the contact pad sets 608A, 608B, 608C, 608D, 608E, 608F, 608G, 608H, 616A, 616B, 616C, 616D, 616E, 616G, 616H can include 8 contact pads (e.g., 5 in addition to those depicted in the illustrated example of FIG. 6, etc.). Additionally, some or all of the contact pad arrays 606A, 606B, 614A, 614B can include additional sets of contact pads.

In the illustrated example of FIG. 6, the first memory die 106A is mounted to the printed circuit board 102 via an example first memory-side contact pad array 504A, and an example fourth memory die 106B is mounted to the printed circuit board 102 via the second memory-side contact pad array 504B. In the illustrated example of FIG. 6, the memory-side contact pad arrays 504A, 504B include the same contact pad configuration of the memory-side contact pad arrays 208A, 208B of FIGS. 4 and 5 (e.g., the memory-side contact pad arrays 504A, 504B include the memory-side contact pads sets 416A, 416B, 416C, 416D, etc.). In other examples, the memory dies 106A, 106B can be mounted to the printed circuit board 102 in any other suitable manner (e.g., via contact pads having different arrangements than the arrangements of the die-side contact pad arrays 606A, 606B, etc.).

To couple the contact pads of the first die-side contact pad array 606A to the first PCB-side contact pad array 616A, the contact pads of the first die-side contact pad array 606A are electrically coupled to a corresponding contact pad of the first PCB-side contact pad array 616A via a trace extending through a layer of the package substrate 604. For example, each contact pad of the first die-side contact pad set 608A is coupled to a corresponding contact pad of the first PCB-side contact pad set 616A via a trace (e.g., the first die-side address contact pad 610A is coupled via a trace to the first PCB-side address contact pad 618A, the first die-side data contact pad 612A is coupled via a trace to the first PCB-side data contact pad 620A, the second die-side data contact pad 612B is coupled via a trace to the second PCB-side data contact pad 620B, etc.). In some examples, each contact pad of the second die-side contact pad set 608B is coupled to a corresponding contact pad of the second PCB-side contact pad set 616B via a trace (e.g., the second die-side address contact pad 610B is coupled via a trace to the second PCB-side address contact pad 618B, the third die-side data contact pad 612C is coupled via a trace to the third PCB-side data contact pad 620C, the fourth die-side data contact pad 612D is coupled via a trace to the fourth PCB-side data contact pad 618D, etc.). In some examples, each contact pad of the third die-side contact pad set 608C is coupled to a corresponding contact pad of the third PCB-side contact pad set 616C via a trace (e.g., the third die-side address contact pad 610C is coupled via a trace to the third PCB-side address contact pad 618C, the fifth die-side data contact pad 612E is coupled via a trace to the fifth PCB-side data contact pad 620E, the sixth PCB-side data contact pad 612F is coupled via a trace to the sixth memory-side data contact pad 620F, etc.). In some examples, each contact pad of the fourth die-side contact pad set 608D is coupled to a corresponding contact pad of the fourth PCB-side contact pad set 616D via a trace (e.g., the fourth die-side address contact pad 610D is coupled via a trace to fourth PCB-side address contact pad 618D, the seventh die-side data contact pad 612G is coupled via a trace to the seventh PCB-side data contact pad 620G, the eighth die-side data contact pad 612H is coupled via a trace to the eighth memory-side data contact pad 620H, etc.). The traces coupling the contact pads of the contact pad arrays 606A, 606B, 614A, 614B are not depicted in the illustrated example of FIG. 6 for visual clarity.

In the illustrated example of FIG. 6, the die-side contact pad arrays 606A, 606B has a same arrangement as the PCB-side contact pad arrays 614A, 614B. In the illustrated example of FIG. 6, the contact pads of the die-side contact pad arrays 606A, 606B and the contact pads of the PCB-side contact pad arrays 614A, 614B are arranged in a 3×4 grid 2d distribution, have the same functional ordering, and the same footprint. In other examples, the contact pads of the contact pad arrays 606A, 606B, 614A, 614B can have a different same arrangement, such as an arrangement including the 2×6 grid 2d distribution of the package-side contact pad arrays 206A, 206B of FIGS. 2 and 4.

In the illustrated example of FIG. 6, the die-side contact pad sets 608A, 608B, 608C, 608D are arranged in the same order as the PCB-side contact pad sets 616A, 616B, 616C, 616D along the lateral axis and have the same internal order of contact pads (e.g., the same ordering of address and data contact pads, etc.). As such, in the illustrated example of FIG. 6, each corresponding pair of contact pads (e.g., the address contact pads 610A, 618A, the address contact pads 610B, 618B, the address contact pads 610C, 618C, the address contact pads 610D, 618D, the data contact pads 612A, 620A, the data contact pads 612B, 620B, the data contact pads 612C, 620C, the data contact pads 612D, 620D, the data contact pads 612E, 620E, the data contact pads 612F, 620E, the data contact pads 612F, 620F, the data contact pads 612G, 620F, the data contact pads 612H, 620H, etc.) are equally offset along the lateral axis. In other examples, each pair of contact pads of the die-side contact pad sets 608A, 608B, 608C, 608D and the PCB-side contact pad sets 616A, 616B, 616C, 616D can be longitudinally aligned. In other examples, the die-side contact pad sets 608A, 608B, 608C, 608D and the PCB-side contact pad sets 616A, 616B, 616C, 616D do not have the same lateral ordering and/or different internal ordering of contact pads. In some such examples, the integrated circuit package 104 can include a memory controller to swap inputs between the individual data contact pads (e.g., bit swapping, etc.) and/or sets of contact pads (e.g., byte swapping, etc.).

The same arrangements of the die-side contact pad arrays 606A, 606B and the PCB-side contact pad arrays 614A, 614B and the associated alignment between corresponding ones of the address contact pads 610A, 610B, 610C, 610D, 618A, 618B, 618C, 618D and corresponding ones of the data contact pads 612A, 612B, 612C, 612D, 612E, 612F, 612G, 612H, 620A, 620B, 620C, 620D, 620E, 620F, 620G, 620H causes the traces in the package substrate 604 connecting the contact pad arrays 606A, 606B, 614A, 614B to extend directly therebetween without fanning out, swizzling, and/or unswizzling. For example, the arrangement of the contact pad arrays 606A, 606B, 614A, 614B enable the traces connecting the contact pads of the die-side contact pad arrays 606A, 606B to directly (e.g., via straight parallel lines, etc.) route between corresponding pads of the contact pad arrays 614A, 614B.

FIG. 7A is a schematic side view of the prior printed circuit board 200. In FIG. 7A, the printed circuit board 200 includes a first layer 700A, a second layer 700B, and a third layer 700C, which include traces of the trace configuration 202 of FIG. 2. In FIG. 7A, the printed circuit board 200 includes an integrated circuit package 702 and a memory die 703. In FIG. 7A, the integrated circuit package 702 and the memory die 703 are coupled to the printed circuit board via a ball grid array 704 and a ball grid array 706, respectively. In FIG. 7A, the integrated circuit package 702 and the memory die 703 are separated by a region 707. In FIG. 7A, the first ball grid array 704 includes a first package-side ball 708A, a second package-side ball 708B, and a third package-side ball 708C. The package-side balls 708A, 708B, 708C are coupled to ones of the contact pads of the first package-side contact pad array 206A of FIGS. 2 and 4. In FIG. 7A, the second ball grid array 706 includes a first memory-side ball 710A, a second memory-side ball 710B, and a third memory-side ball 710C. The memory-side balls 710A, 710B, 710C are coupled to ones of the contact pad array 208A of FIGS. 2 and 4. It should be appreciated that the ball grid arrays 704, 706 include additional balls, which are correspondingly coupled via traces disposed in the printed circuit board 200 (e.g., in layers 700A, 700B, 700C, in other layers of the printed circuit board 200, etc.).

In FIG. 7A, the first package-side ball 708A and the first memory-side ball 710A are coupled via a first trace 712A. In FIG. 7A, the second package-side ball 708B and the second memory-side ball 710B are coupled via a second trace 712B. In FIG. 7A, the third package-side ball 708C and the third memory-side ball 710C are coupled via the third trace 712C. In FIG. 7A, the first trace 712A, the second trace 712B, and the third trace 712C are disposed in the third layer 700C, the second layer 700B, and the first layer 700A, respectively.

In FIG. 7A, the different arrangements of the first package-side contact pad array 206A and the first memory-side contact pad array 208A causes the package-side balls 708A, 708B, 708A and the memory-side balls 710A, 710B, 710C to be disposed in different orders. Particularly, in FIG. 7A, the first package-side ball 708A is distal to the region 707 (e.g., farthest from the memory die 703, etc.), the third package-side ball 708C is adjacent to the region 707 (e.g., closest to the memory die 703, etc.), and the second package-side ball 708B is between the first package-side ball 708A and the third package-side ball 708C. In FIG. 7A, the third memory-side ball 710C is distal to the region 707 (e.g., farthest from the integrated circuit package 702, etc.), the second memory-side ball 710B is adjacent to the region 707 (e.g., closest to the integrated circuit package 702, etc.), and the first memory-side ball 710A is between the first memory-side ball 710A and the third memory-side ball 710C. That is, the different arrangements of the first package-side contact pad array 206A and the first memory-side contact pad array 208A causes the ordering of the package-side balls 708A, 708B, 708C and the ordering of the memory-side balls 710A, 710B, 710C to be different. Further, as discussed above in connection with FIG. 4, different pairs of the contact pads in the contact pad arrays 206A, 208A are not longitudinally aligned along the X axis. As such, in FIG. 7A, the balls 708A, 708B, 708C, 710A, 710B, 710C are not longitudinal aligned but are at different lateral positions into and out of the page (e.g., along the Y axis). Thus, FIG. 7A should not be understood as being a cross-section along a single plane normal to the Y axis.

In FIG. 7A, the different ordering of the package-side balls 708A, 708B, 708C and the memory-side balls 710A, 710B, 710C and the different lateral positions of the balls 708A, 708B, 708C, 710A, 710B, 710C results in the need for the traces 712A, 712B, 712C to follow indirect (e.g., non-linear) paths that extend around one another to define a complete signal path between the corresponding pair of balls 708A, 708B, 708C, 710A, 710B, 710C. In FIG. 7A, the indirect paths of the traces 712A, 712B, 712C are illustrated by the traces shown as intersecting and/or crossing one another. It should be appreciated that the traces of the prior printed circuit board 200 do not cross to prevent signal loss and/or interference. Instead, the traces 712A, 712B, 712C extend into and out of the page of FIG. 7A, which contributes to the swizzling, unswizzling, and fanning-out of the prior trace configuration 202.

FIG. 7B is a schematic side view of the example printed circuit board 102 of FIG. 1 including the traces 110. In the illustrated example of FIG. 7B, the printed circuit board 102 includes an example first layer 713A, an example second layer 713B, and an example third layer 713C. In the illustrated example of FIG. 7B, the printed circuit board assembly 100 includes the integrated circuit package 104 of FIG. 1 and the first memory die 106A, which are separated by the third region 312 of FIG. 3. In the illustrated example of FIG. 7B, the integrated circuit package 702 and the memory die 703 are coupled to the printed circuit board via an example package-side ball grid array 714 and an example memory-side ball grid array 716, respectively.

In the illustrated example of FIG. 7B, the first ball grid array 704 includes an example first package-side ball 718A, an example second package-side ball 718B, and an example third package-side ball 718C. In the illustrated example of FIG. 7B, the package-side balls 718A, 718B, 718C are coupled to ones of the contact pads of the first package-side contact pad array 304A of FIG. 3. In the illustrated example of FIG. 7B, the second ball grid array 706 includes an example first memory-side ball 720A, an example second memory-side ball 720B, and an example third memory-side ball 720C. In the illustrated example of FIG. 7B, the memory-side balls 720A, 720B, 720C are coupled to ones of the array of the first memory-side contact pad array 306A of FIG. 3. It should be appreciated that the ball grid arrays 714, 716 can include additional balls, which are correspondingly mounted on other contact pads of the contact pad arrays 304A, 306A, respectively, and coupled via traces disposed in the example printed circuit board 102 (e.g., in layers 713A, 713B, 713C, in other layers of the printed circuit board 102, etc.). The ball grid arrays 714, 716 have arrangements that are the same as the arrangements of the contact pad arrays 304A, 306A, respectively. That is, the ball grid arrays 714, 716 have a same footprint, a same 2d distribution, and a same functional ordering.

Unlike the balls 708A, 708B, 708C, 710A, 710B, 710C of the ball grid arrays 704, 706 of FIG. 7A, the ordering of the package-side balls 718A, 718B, 718C and the memory-side balls 720A, 720B, 720C are mirrored relative to the region 707. That is, in the illustrated example of FIG. 7B, the arrangements of the contact pad arrays 304A, 306A causes the ordering of the package-side balls 718A, 718B, 718C and the memory-side balls 720A, 720B, 720C to be the same relative to the region 312 (e.g., the first package-side ball 718A and the first memory-side ball 720A are farthest from the third region 312, the third package-side ball 718C and the third memory-side ball 720C are closest to the third region 312, etc.). That is, the functional ordering of the package-side balls 718A, 718B, 718C has a functional ordering that is mirrored to the functional ordering of the memory-side balls 720A, 720B, 720C.

Further, unlike the balls 708A, 708B, 708C, 710A, 710B, 710C in FIG. 7A that are laterally offset (e.g., along the Y axis) relative to one another, the balls 718A, 718B, 718C, 720A, 720B, 720C in FIG. 7B are longitudinally aligned. That is, unlike in FIG. 7A, the balls 718A, 718B, 718C, 720A, 720B, 720C in FIG. 7B all lie on the same plane normal to the Y axis. The same arrangements of the package-side contact pad arrays 304A, 304B and the associated functional ordering and longitudinal alignment of the package-side balls 718A, 718B, 718C and the memory-side balls 720A, 720B, 720C causes the traces 722A, 722B, 722C of the trace configuration 300 to extend directly between corresponding ones of the balls 718A, 718B, 718C, 720A, 720B, 720C.

Unlike in FIG. 7A, the traces 722A, 722B, 722C in FIG. 7B do not intersect or cross one another as there is no need for the traces to go around one other because the traces 722A, 722B, 722C extend in the same direct (e.g., parallel to one another). Particularly, in the illustrated example of FIG. 7B, the first trace 722A is disposed in the third layer 713C (e.g., the lowest layer of the printed circuit board 102, etc.) and the outermost balls of the ball grid arrays 714, 716 (e.g., the first package-side ball 718A and the first memory-side ball 720A, etc.). In the illustrated example of FIG. 7B, the second trace 722B is disposed in the second layer 713B (e.g., the middle layer of the printed circuit board 102, etc.), and the middle balls of the ball grid arrays 714, 716 (e.g., the second package-side ball 718B and the second memory-side ball 720B, etc.). In the illustrated example of FIG. 7B, the third trace 722C is disposed in the first layer 713A (e.g., the top layer of the printed circuit board 102, etc.), and the innermost balls of the ball grid arrays 714, 716 (e.g., the third package-side ball 718C and the third memory-side ball 720C, etc.).

The lack of intersection of the traces 722A, 722B, 722C mitigates (e.g., reduces, prevents, etc.) the need for the traces 722A, 722B, 722C of the trace configuration 300 to extend into and out of the page of FIG. 7B. In some such examples, the arrangement of the contact pad arrays 304A, 306A and the associated ordering of the balls 718A, 718B, 718C, 720A, 720B, 720C enables the straight direct routing of the traces 722A, 722B, 722C without the need for the traces 722A, 722B, 722C to fanout, swizzle, and unswizzle. While the traces 722A, 722B, 722C are depicted as ordered vertically (e.g., in the layers 713A, 713B, 713C, etc.) in the illustrated example of FIG. 7B, the ordering of the balls 718A, 718B, 718C, 720A, 720B, 720C enables the traces 722A, 722B, 722C to be routed in a same layer (e.g., the first layer 713A, etc.). Such same layer routing is not possible in the prior printed circuit board 200 of FIG. 7A due to the functional ordering of the balls 708A, 708B, 708C, 710A, 710B, 710C.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

Printed circuit boards including direct routing from integrated circuit packages are disclosed herein. Further examples and combinations thereof include the following:

Example 1 includes a substrate comprising a first contact pad array to receive an integrated circuit package, a second contact pad array to receive a memory die, the first contact pad array having a matching arrangement as the second contact pad array, and a layer including a plurality of interconnections extending between the first contact pad array and the second contact pad array.

Example 2 includes the substrate of example 1, wherein the memory die is a dynamic random access memory unit.

Example 3 includes the substrate of example 1, wherein the integrated circuit package is a system-on-chip package.

Example 4 includes the substrate of example 1, wherein a distance between the first contact pad array and the second contact pad array is less than 7 millimeters.

Example 5 includes the substrate of example 1, further including a first region corresponding to the integrated circuit package, a second region corresponding to the memory die, and a third region between the first region and the second region, the interconnections parallel in the third region.

Example 6 includes the substrate of example 5, wherein the layer is a first layer, the interconnections are first interconnections, and further including a second layer including second interconnections extending between the first contact pad array and the second contact pad array.

Example 7 includes the substrate of example 6, wherein (a) the first layer is to be between the second layer and the integrated circuit package, (b) the first contact pad array includes a first pad adjacent to the third region (c) the second contact pad array includes a second pad adjacent to the third region and (d) the first interconnections include a first interconnection coupling the first pad and the second pad.

Example 8 includes the substrate of example 6, wherein the second interconnections are parallel to the first interconnections in the third region.

Example 9 includes the substrate of example 1, wherein the first contact pad array includes a first plurality of data contact pads and a first plurality of address contact pads, the second contact pad array includes a second plurality of data contact pads and a second plurality of address contact pads, each of the first plurality of data contact pads longitudinally aligned with corresponding ones of the second plurality of data contact pads, and each of the first plurality of address contact pads longitudinally aligned with corresponding ones of the second plurality of address contact pads.

Example 10 includes an apparatus comprising a memory die, an integrated circuit package, and a printed circuit board including a first contact pad array, the memory die coupled to the printed circuit board via the first contact pad array, the first contact pad array including a first set of contact pads distributed along a first line, a second contact pad array, the integrated circuit package coupled to the printed circuit board via the second contact pad array, the second contact pad array including a second set of contact pads distributed along a second line, the first line parallel to the second line, and a plurality of traces, different ones of the traces electrically coupling different ones of the contact pads in the first set with respective ones of the contact pads in the second set.

Example 11 includes the apparatus of example 10, wherein the first line is colinear with the second line.

Example 12 includes the apparatus of example 10, wherein a distance between the memory die and the integrated circuit package is less than 7 millimeters.

Example 13 includes the apparatus of example 10, wherein the printed circuit board includes a first portion associated with the integrated circuit package, a second portion associated with the memory die, and a third portion between the first portion and the second portion, the traces parallel in the third portion.

Example 14 includes the apparatus of example 13, wherein the first set of contact pads has a first functional ordering of first data contact pads and first address contact pads, the second set of contact pads has a second functional ordering of second data contact pads and second address contact pads, and the first functional ordering is symmetrical to the second functional ordering relative to the third portion.

Example 15 includes the apparatus of example 13, wherein the traces are disposed in a first layer of the printed circuit board, the traces are first traces, and the printed circuit board includes a second layer including second traces extending between the first contact pad array and the second contact pad array, the second traces parallel in the third portion.

Example 16 includes the apparatus of example 15, wherein the first traces are parallel to the second traces.

Example 17 includes the apparatus of example 13, wherein the third portion is laterally bound by at least one of the integrated circuit package or the memory die and the traces do not extend outside of the first portion, the second portion or the third portion.

Example 18 includes the apparatus of example 10, wherein the first contact pad array has a first plurality of data bits and a first plurality of command/address bits, the second contact pad array includes having second plurality of data bits and a second plurality of command/address bits, each of the first plurality of data bits longitudinally aligned with corresponding ones of the second plurality of data bits, and each of the first plurality of command/address bits longitudinally aligned with corresponding ones of the second plurality of command/address bits.

Example 19 includes a system comprising a memory die including a first ball grid array, the first ball grid array including first balls distributed having a first two-dimensional distribution and a first footprint, and an integrated circuit package including a second ball grid array, the second ball grid array including second balls having a second two-dimensional distribution and a second footprint, the first two-dimensional distribution matching the second two-dimensional distribution, the first footprint having a same size and a same shape as the second footprint.

Example 20 includes the system of example 19, further including a first set of the first balls including a first memory-side ball, a second memory-side ball, and a third memory-side ball, the first memory-side ball, the second memory-side ball, and the third memory-side ball having a first functional ordering, and a second set of the second balls including a first package-side ball, a second package-side ball, and a third package-side ball, the first package-side ball, the second package-side ball, and the third package-side ball having a second ordering, the second functional ordering mirrored relative to the first functional ordering.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A substrate comprising:
a first contact pad array to receive an integrated circuit package;
a second contact pad array to receive a memory die, the first contact pad array having a matching arrangement as the second contact pad array; and
a layer including a plurality of interconnections extending between the first contact pad array and the second contact pad array.

2. The substrate of claim 1, wherein the memory die is a dynamic random access memory unit.

3. The substrate of claim 1, wherein the integrated circuit package is a system-on-chip package.

4. The substrate of claim 1, wherein a distance between the first contact pad array and the second contact pad array is less than 7 millimeters.

5. The substrate of claim 1, further including:
a first region corresponding to the integrated circuit package;
a second region corresponding to the memory die; and
a third region between the first region and the second region, the interconnections parallel in the third region.

6. The substrate of claim 5, wherein the layer is a first layer, the interconnections are first interconnections, and further including a second layer including second interconnections extending between the first contact pad array and the second contact pad array.

7. The substrate of claim 6, wherein (a) the first layer is to be between the second layer and the integrated circuit package, (b) the first contact pad array includes a first pad adjacent to the third region (c) the second contact pad array includes a second pad adjacent to the third region and (d) the first interconnections include a first interconnection coupling the first pad and the second pad.

8. The substrate of claim 6, wherein the second interconnections are parallel to the first interconnections in the third region.

9. The substrate of claim 1, wherein the first contact pad array includes a first plurality of data contact pads and a first plurality of address contact pads, the second contact pad array includes a second plurality of data contact pads and a second plurality of address contact pads, each of the first plurality of data contact pads longitudinally aligned with corresponding ones of the second plurality of data contact pads, and each of the first plurality of address contact pads longitudinally aligned with corresponding ones of the second plurality of address contact pads.

10. An apparatus comprising:
a memory die;
an integrated circuit package; and
a printed circuit board including:
a first contact pad array, the memory die coupled to the printed circuit board via the first contact pad array, the first contact pad array including a first set of contact pads distributed along a first line;
a second contact pad array, the integrated circuit package coupled to the printed circuit board via the second contact pad array, the second contact pad array including a second set of contact pads distributed along a second line, the first line parallel to the second line; and
a plurality of traces, different ones of the traces electrically coupling different ones of the contact pads in the first set with respective ones of the contact pads in the second set.

11. The apparatus of claim 10, wherein the first line is colinear with the second line.

12. The apparatus of claim 10, wherein a distance between the memory die and the integrated circuit package is less than 7 millimeters.

13. The apparatus of claim 10, wherein the printed circuit board includes:
a first portion associated with the integrated circuit package;
a second portion associated with the memory die; and
a third portion between the first portion and the second portion, the traces parallel in the third portion.

14. The apparatus of claim 13, wherein the first set of contact pads has a first functional ordering of first data contact pads and first address contact pads, the second set of contact pads has a second functional ordering of second data contact pads and second address contact pads, and the first functional ordering is symmetrical to the second functional ordering relative to the third portion.

15. The apparatus of claim 13, wherein the traces are disposed in a first layer of the printed circuit board, the traces are first traces, and the printed circuit board includes a second layer including second traces extending between the first contact pad array and the second contact pad array, the second traces parallel in the third portion.

16. The apparatus of claim 15, wherein the first traces are parallel to the second traces.

17. The apparatus of claim 13, wherein the third portion is laterally bound by at least one of the integrated circuit package or the memory die and the traces do not extend outside of the first portion, the second portion or the third portion.

18. The apparatus of claim 10, wherein the first contact pad array has a first plurality of data bits and a first plurality of command/address bits, the second contact pad array includes having second plurality of data bits and a second plurality of command/address bits, each of the first plurality of data bits longitudinally aligned with corresponding ones of the second plurality of data bits, and each of the first plurality of command/address bits longitudinally aligned with corresponding ones of the second plurality of command/address bits.

19. A system comprising:
a memory die including a first ball grid array, the first ball grid array including first balls distributed having a first two-dimensional distribution and a first footprint; and
an integrated circuit package including a second ball grid array, the second ball grid array including second balls having a second two-dimensional distribution and a second footprint, the first two-dimensional distribution matching the second two-dimensional distribution, the first footprint having a same size and a same shape as the second footprint.

20. The system of claim 19, further including
a first set of the first balls including:
a first memory-side ball;
a second memory-side ball; and
a third memory-side ball, the first memory-side ball, the second memory-side ball, and the third memory-side ball having a first functional ordering; and
a second set of the second balls including:
a first package-side ball;
a second package-side ball; and
a third package-side ball, the first package-side ball, the second package-side ball, and the third package-side ball having a second ordering, the second functional ordering mirrored relative to the first functional ordering.
